(19) United States
(12) Patent Application Publication
(10) Pub. No.: US 2025/0385237 A1
(43) Pub. Date: Dec. 18, 2025

(54) MONOLITHIC-LIKE INTEGRATION OF SEMICONDUCTOR STRUCTURES

(71) Applicant: Google LLC, Mountain View, CA (US)

(72) Inventors: Anup Pancholi, Palo Alto, CA (US); Hsien Kang Michael Kao, Cupertino, CA (US)

(21) Appl. No.: 19/240,679

(22) Filed: Jun. 17, 2025

Related U.S. Application Data
(60) Provisional application No. 63/660,932, filed on Jun. 17, 2024.

(51) Int. Cl. H01L 25/18; H01L 21/683; H01L 23/00; H10B 80/00; H10D 80/30

(52) U.S. Cl. CPC H01L 25/18; H01L 21/6835; H01L 24/08; H01L 24/80; H10B 80/00; H10D 80/30; H01L 2224/08145; H01L 2224/80895; H01L 2224/80896; H01L 2924/1431

(57) ABSTRACT

The present disclosure generally relates to semiconductor devices and fabrication processes, and more specifically, to techniques for integrating multiple semiconductor structures using advanced semiconductor processing and packaging methods. In one example, a semiconductor device is provided. The semiconductor device includes a first semiconductor structure, a second semiconductor structure, and a bonding structure. The first semiconductor structure can include logic circuits configured to perform logic processing functions. The second semiconductor structure can include a memory device and can be stacked over the first semiconductor structure. The bonding structure is between the first semiconductor structure and the second semiconductor structure.

### CROSS-REFERENCE TO RELATED APPLICATIONS

This application claims the benefit of U.S. Provisional Application Ser. No. 63/660,932 filed on Jun. 17, 2024, titled “Monolithic-Like Integration of Semiconductor Structures,” the entire contents of which are hereby incorporated by reference in its entirety.

### TECHNICAL FIELD

This specification generally relates to semiconductor devices and fabrication processes, and more specifically, to techniques for integrating multiple semiconductor structures using advanced semiconductor processing and packaging methods.

### BACKGROUND

Modern computing platforms, including mobile system-on-chip (SoC) architectures, are being used to handle intensive machine learning (ML) and artificial intelligence (AI) workloads. These platforms often use logic and memory devices connected through conventional interfaces and integration techniques. As ML models continue to grow in size, computing platforms are exposed to heightened operating demands. As such, the performance of computing platforms using conventional integration techniques can be constrained by the limited memory bandwidth and increased thermals from the data traffic between the logic and memory devices.

### SUMMARY

Mobile computing platforms are being used for a range of edge operations, including processing related to machine learning (ML) operations. An example mobile computing platform can include multiple semiconductor devices, such as a logic/processing device and a memory device, that are generally implemented on separate silicon wafers. In such platforms, the logic and memory devices are coupled together using conventional interfaces and integration techniques.

In the context of ML operations, such platforms generally use a computing architecture (e.g., Von Neumann architecture) in which the ML models and associated data are loaded from the memory device, processed by the logic/processing device, and stored back in memory.

As ML models continue to grow in size, computing platforms are exposed to heightened operating demands. Indeed, particular types of models, such as large language models (LLMs), generally have the following operating parameters to achieve increasing (1) larger memory capacity (e.g., for loading the LLM from storage to memory), (2) higher memory bandwidth (e.g., to enhance attainable performance), and (3) lower energy consumption (e.g., as data traverses between the logic and memory devices/units).

Such heightened ML operating demands are particularly observable in the context of mobile system-on-chip (SOC) architectures, which are generally limited by performance (offline to online) and thermal capacity (given the battery-powered operation), but nevertheless are increasingly being used for a range of compute and memory intensive ML-driven user applications (e.g., voice recording, image processing, digital assistants). Multiple optimizations of the ML processing can be done to address these issues. These include, e.g., partitioning the ML into compute bound workload and memory bound workload and/or model optimizations (e.g., compression, sparsity, quantization, graph sharding, etc.), which can be implemented to enhance attainable performance for compute bound workload and memory bound workload. Even with these optimizations, performance in such architectures is generally constrained by the limited memory bandwidth and increased thermals from the data traffic between the logic and memory devices for these models.

In view of the above, this specification describes hardware design and integration schemes involving advanced semiconductor processing and packaging, which are summarized below and discussed in greater detail throughout this document and with reference to FIGS. 1-4.

In some implementations, the integration scheme includes manufacturing two separate semiconductor structures (e.g., in parallel or sequentially) and bonding them together (e.g., through hybrid bonding). The first semiconductor structure (which can include, e.g., a mobile SoC) can be manufactured as follows. First, a front-end transistor layer can be formed on a substrate. For example, the substrate can be a silicon (Si) wafer. Second, a signal interconnect metal layer can be formed on the front-end transistor layer. Third, the front-end transistor layer of the semiconductor structure can be bonded (e.g., using fusion bonding) to a carrier wafer. Thereafter, the substrate can be removed from the semiconductor structure using bulk silicon removal techniques, such as wafer grinding, chemical mechanical planarization (CMP), and/or etching.

The second semiconductor structure (which can include, e.g., a memory device) can be manufactured by forming a memory layer on a new substrate. In some implementations, the memory layer can include one or more of: DRAM or another memory unit, and/or an in-compute memory (e.g., processor-in-memory (PIM)).

The first and second semiconductor structures can then be coupled together, e.g., using a hybrid bonding coupling technique, after which the substrate can be removed using, e.g., bulk silicon removal techniques. In some implementations, additional layers can be stacked/formed over the memory and logic devices. For example, a power interconnect metal layer can be formed over the memory layer, and microbumps can be coupled to this power interconnect layer.

Implementations of the integration scheme described in this specification can use semiconductor process technologies such as hybrid bonding (e.g., wafer-to-wafer), layer transfer, and extreme bulk silicon removal process. The described techniques can be applied to integrating or stacking a memory component (e.g., dynamic random access memory (DRAM), processor-in-memory (PIM), or other emerging memory of last level caching) on a logic device. The techniques can also be used to integrate any other functional IP blocks or devices (e.g., graphics processing unit (GPU)) to provide monolithic-like performance.

While for ease of description, a stacked structure including two semiconductor structures may be used as an example in this specification, it is understood that the described techniques can be used to stack and bond any number of semiconductor structures. Each of the bonded semiconductor structures can include one or more logic devices or memory devices, or a combination thereof. It is also understood that the integration scheme can be applied to fabrication of any semiconductor devices configured to perform in-memory compute. In some instances, the described integration scheme allows the in-memory compute to be performed at low energy per bit and to enable power and performance efficient edge AI capabilities.

One aspect of the subject matter described in this specification can be embodied in a semiconductor device. The semiconductor device includes a first semiconductor structure, a second semiconductor structure, and a bonding structure. The first semiconductor structure can include logic circuits configured to perform logic processing functions. The second semiconductor structure can include a memory device and can be stacked over the first semiconductor structure. The bonding structure is between the first semiconductor structure and the second semiconductor structure.

In some implementations, the first semiconductor structure can include a logic device. The logic device can include the logic circuits. The logic device can include at least one of a central processing unit (CPU), a graphics processing unit (GPU), an application-specific integrated circuit (ASIC), an application processor (AP), a tensor processing unit (TPU), or a system-on-chip (SoC).

In some implementations, the memory device includes one or more memory cell arrays.

In some implementations, the memory device further includes one or more processor-in-memory (PIM) units coupled to the one or more memory cell arrays.

In some implementations, the bonding structure includes conductive contacts and a dielectric material isolating the conductive contacts. The conductive contacts are configured to transfer data and power between the logic circuits of the first semiconductor structure and the memory device of the second semiconductor structure.

In some implementations, the first semiconductor structure further includes a first interconnect layer coupled to the logic circuits. The semiconductor device further includes a second interconnect layer coupled to the second semiconductor structure. The second interconnect layer can be configured to provide power to the first semiconductor structure and the second semiconductor structure.

Another aspect of the subject matter described in this specification can be embodied in a method for manufacturing a semiconductor device. The method includes: forming a first semiconductor structure that includes logic circuits configured to perform logic processing functions; forming a second semiconductor structure that includes one or more memory cell arrays; stacking the second semiconductor structure over the first semiconductor structure; and bonding the second semiconductor structure to the first semiconductor structure.

In some implementations, forming the first semiconductor structure includes: forming an ordered logic circuit component stack that includes: a first substrate, a transistor layer formed on the first substrate, and a first interconnect layer formed on the transistor layer and bonded to a carrier wafer; and removing the first substrate from the ordered logic circuit component stack to obtain the first semiconductor structure.

In some implementations, the first interconnect layer is bonded to the carrier wafer using a fusion bonding technique.

In some implementations, the transistor layer includes a logic device. The logic device can include the logic circuits. The logic device can include at least one of a central processing unit (CPU), a graphics processing unit (GPU), an application-specific integrated circuit (ASIC), an application processor (AP), a tensor processing unit (TPU), or a system-on-chip (SoC).

In some implementations, forming the second semiconductor structure includes: forming a second substrate; and forming a memory layer on the second substrate. The memory layer can include the one or more memory cell arrays. The second semiconductor structure can include the second substrate and the memory layer.

In some implementations, forming the memory layer further includes: forming one or more processor-in-memory (PIM) units in the memory layer.

In some implementations, bonding the second semiconductor structure to the first semiconductor structure includes: bonding the memory layer of the second semiconductor structure to the transistor layer of the first semiconductor structure.

In some implementations, the second semiconductor structure is bonded to the first semiconductor structure using a hybrid bonding technique. Bonding the memory layer of the second semiconductor structure to the transistor layer of the first semiconductor structure can include: forming a first bonding layer coupled to the transistor layer, where the first bonding layer includes first conductive contacts and a first dielectric material isolating the first conductive contacts; forming a second bonding layer coupled to the memory layer, where the second bonding layer includes second conductive contacts and a second dielectric material isolating the second conductive contacts; and forming a bonding structure by bonding the second bonding layer to the first bonding layer, where the second conductive contacts are aligned with the first conductive contacts, and the bonding structure includes the first bonding layer and the second bonding layer.

In some implementations, the method further includes: removing the second substrate from the second semiconductor structure; and forming a second interconnect layer on the memory layer. The second interconnect layer can be configured to provide power to the memory layer and the transistor layer.

In some implementations, the method further includes: forming third conductive contacts coupled to the second interconnect layer, where the third conductive contacts are configured to provide electrical connections to an external component.

Another aspect of the subject matter described in this specification can be embodied in a semiconductor device. The semiconductor device includes a first semiconductor structure that includes a first device; a second semiconductor structure that includes a second device; and a bonding structure between the first semiconductor structure and the second semiconductor structure.

In some implementations, the first device includes at least one of a first logic device or a first memory device, the first logic device includes first logic circuits configured to perform logic processing functions, and the first memory device includes one or more first memory cell arrays.

In some implementations, the second device includes at least one of a second logic device or a second memory device, the second logic device includes second logic circuits configured to perform logic processing functions, and the second memory device includes one or more second memory cell arrays.

In some implementations, the bonding structure includes conductive contacts and a dielectric material isolating the conductive contacts, and the conductive contacts are configured to transfer data and power between the first device and the second device.

Particular embodiments of the subject matter described in this specification can be implemented so as to realize one or more of the following advantages. First, on demand memory capacity expansion can be achieved using novice three-dimensional (3D) stacking. In other words, memory devices can be vertically integrated over logic devices, thereby allowing high-density memory integration within a compact footprint. Second, the techniques can increase memory bandwidth using the heterogeneous integration with finer bonding pitch, thereby allowing higher input/output (I/O) density designs and reducing I/O shoreline overhead. Third, the integration techniques described herein achieve a functional subsystem, with arithmetic logic unit (ALU) and registers in the proximity of memory cell arrays, which in turn improves system performance. Fourth, end-to-end data latency can be improved with short reach (SR) capability from the integration scheme without penalty from the protocol handling and signal integrity. Fifth, data movement energy (e.g., measured in Joule/bit) stemming from the integration that results in additional memory capacity and/or processing-in-memory (PIM) being in close proximity to the logic device can be reduced (thereby resulting in improved power and performance). Sixth, the described techniques allow two separate semiconductor structures to be manufactured independently or in parallel and then bonded together, which can reduce overall cost and improve production yield.

These and additional features of the above techniques are described further below with reference to FIGS. 1-4.

### BRIEF DESCRIPTION OF THE DRAWINGS

FIG. 1 is a block diagram of an example computing system.

FIG. 2 is a schematic illustration of an example semiconductor device that includes stacked semiconductor structures.

FIG. 3 illustrates an example process of manufacturing a semiconductor device.

FIG. 4 illustrates a flow chart of an example manufacturing process.

Like reference numbers and designations in the various drawings indicate like elements.

### DETAILED DESCRIPTION

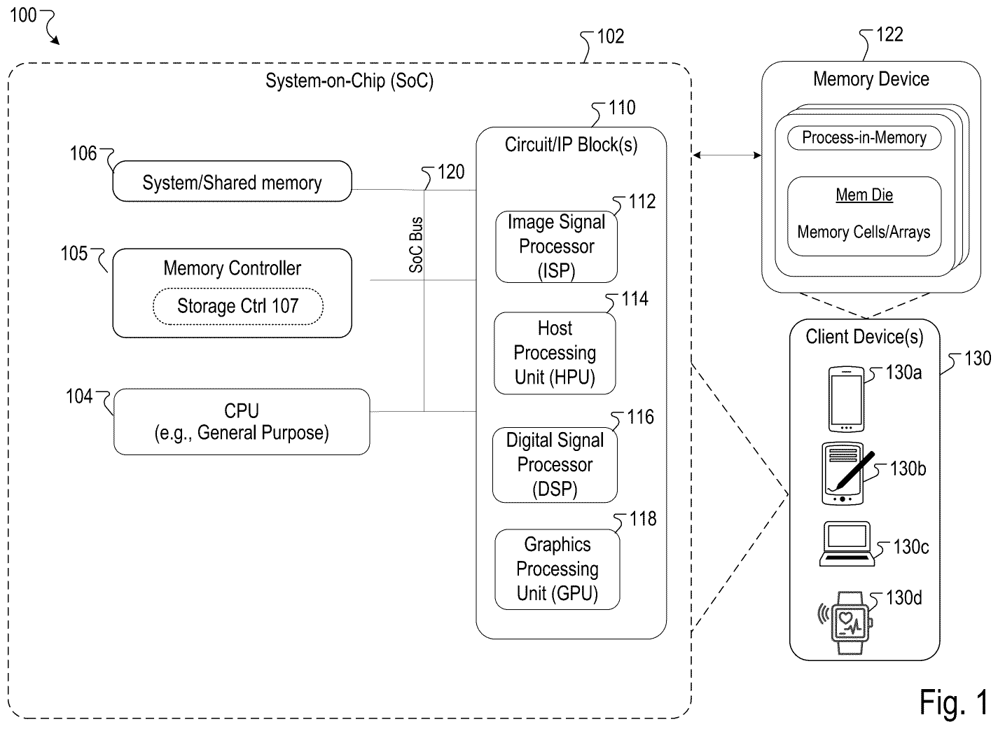

FIG. 1 is a block diagram of an example computing system 100 that includes a system-on-chip 102 (“SoC 102”). In some implementations, the computing system 100 is implemented on a user/client device 130. The SoC 102 includes a central processing unit 104 (“CPU 104”), a memory controller 105, a shared memory 106 (“memory 106”), and an IP/circuit block 110. In some implementations, system 100 can include multiple SoCs and any descriptions for the SoC 102 herein are equally applicable to each of the multiple SoCs that may be included at system 100.

The memory 106 can be a system memory, shared memory, or both. In the example of FIG. 1, memory 106 is depicted external to the IP/circuit block 110. However, memory 106 can include portions of memory that are: i) specific to circuit block 110, ii) external to the IP/circuit block 110, or iii) both. The memory 106 can be random access memory of the SoC 102, such as static random access memory (SRAM), dynamic random access memory (DRAM), a synchronous DRAM (SDRAM), or double data rate (DDR) SDRAM.

In some implementations, aspects of memory 106 are configured as a shared scratchpad memory that supports parallel access of its memory resources by two or more processors of the IP/circuit 110. Memory 106 can also include various other types of memory, such as high bandwidth memory (HBM), narrow memory (e.g., for storing 8-bit values), wide memory (e.g., for storing 16-bit or 32-bit values), etc.

The IP/circuit block 110 generally includes individual IP devices such as processors, processor cores, or special-purpose processing devices. For example, the IP/circuit block 110 can include an image signal processor (ISP) 112, a host processing unit (HPU) 114, a digital signal processor (DSP) 116, and a graphics processing unit (GPU) 118. The IP/circuit block 110 is referred to alternatively as an IP block 110, where the IP block can include one or more hardware elements. For example, each of the ISP 112, HPU 114, DSP 116, and GPU 118 can be a respective IP block (or IP device) of a particular entity or device manufacturer.

The HPU 114 can be a special-purpose processor, such as machine-learning hardware accelerator, neural processor unit, neural network processor, or an application-specific processor. In some implementations, the HPU 114 is a neural network tensor processor that includes an integrated circuit architecture configured for power-efficient execution of machine-learning computations using tensor constructs such as multi-dimensional matrices.

The CPU 104 can be configured as an instruction and vector data processing engine that processes data obtained from a system memory of the SoC 102, such as memory 106. In some implementations, each processor (e.g., ISP 112, DSP 116, HPU 114, GPU 118) of the SoC 102 includes multiple cores.

The system 100 includes a memory device 122. The memory device 122 can include multiple memory dies. For example, the memory device 122 can include N memory die, where N is an integer greater than or equal to 1. The memory device 122 can be a dynamic random-access memory (DRAM) or Double Data Rate (DDR) synchronous DRAM (SDRAM). The memory device 122 is configured to perform or support various types of PIM operations and memory-near-computing operations (“MnC operations”). The memory device 122 performs or supports these operations using its multiple PIM compute elements.

The SoC 102 can cooperate with its internal memories such as (the memory 106) and the memory device 122 to perform computations across one or more bank groups of the memory device 122. For example, the memory 106 can be configured to perform local processing and offload some operations of the memory device 122.

In the example of FIG. 1, the SoC 102 is an integrated circuit of an example user/client device 130, consumer electronic device, or mobile device, where each of these devices can include items such as a smartphone 130a, tablet 130b, laptop 130c, smartwatch or wearable device 130d. The devices 130 may also include, e.g., an eNotebook, Netbook, smart speaker, or mobile computer. In some implementations, the system 100 and the SoC 102 are integrated circuits of a desktop computer, network server, or related cloud-based asset.

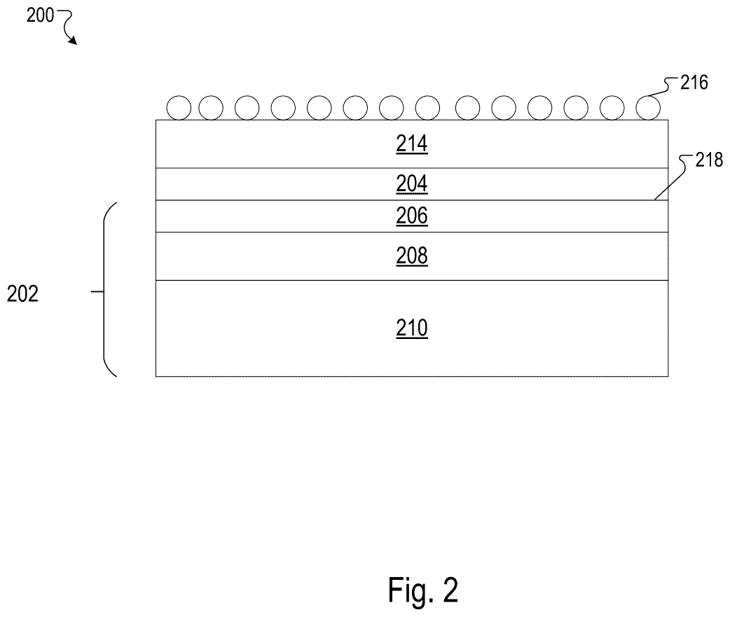

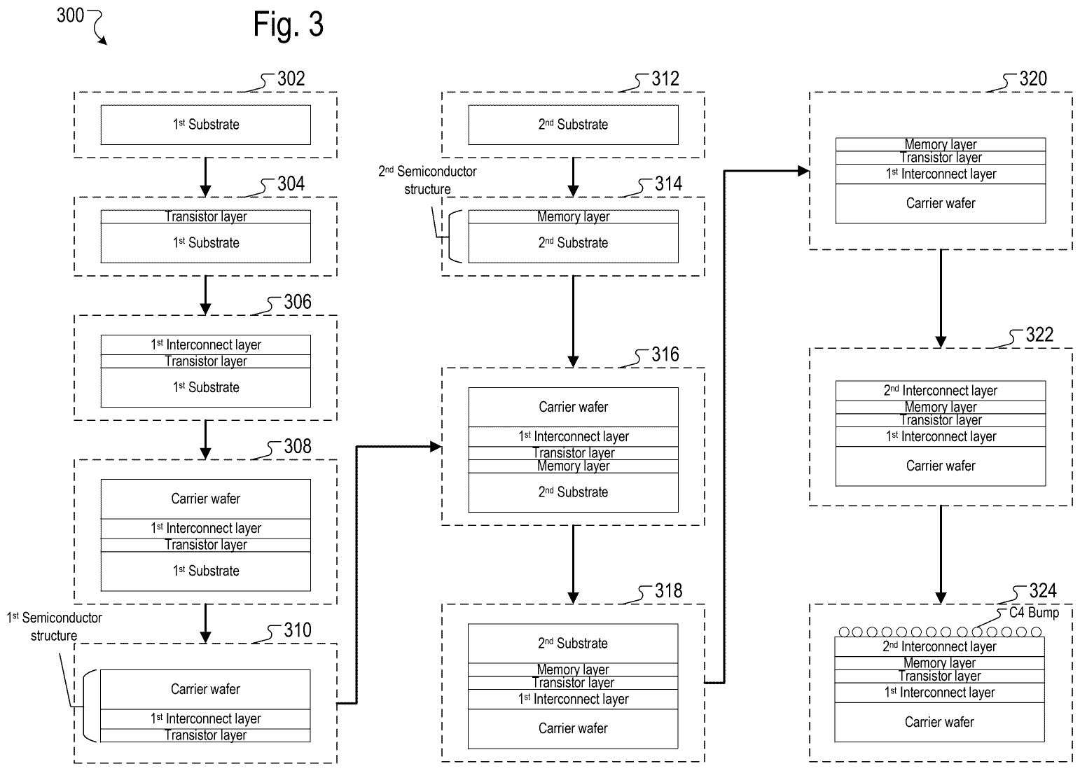

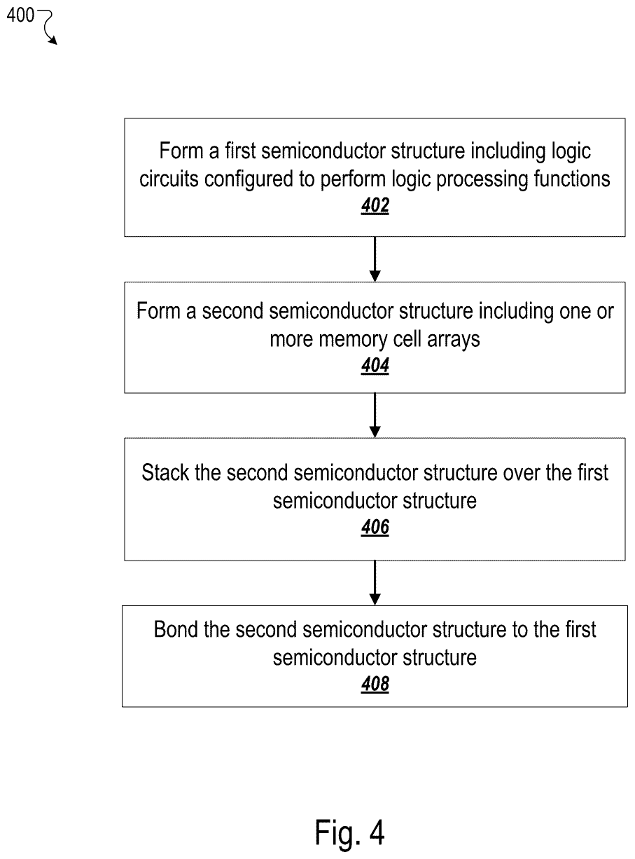

FIG. 2 is a schematic view of an example semiconductor device 200. The semiconductor device 200 can be a bonded device. As shown in FIG. 2, the semiconductor device 200 includes a first semiconductor structure 202 and a second semiconductor 204 stacked over and bonded to the first semiconductor structure 202. Techniques for fabricating and bonding the semiconductor structures are described with reference to FIGS. 3 and 4 below.

The first semiconductor structure 202 can include one or more logic devices 206. The second semiconductor structure 204 can include one or more memory devices. Each of the logic devices 206 can include logic circuits configured to perform logic processing functions. For example, the logic device 206 can include at least one of a central processing unit (CPU), a graphics processing unit (GPU), an application-specific integrated circuit (ASIC), an application processor (AP), a host processing unit (HPU), or a system-on-chip (SoC). Each of the memory devices can include one or more memory cell arrays. In some implementations, the memory device of the second semiconductor structure 204 can further include one or more processor-in-memory (PIM) units coupled to the one or more memory cell arrays.

In some implementations, the semiconductor device 200 can include the memory 122 and the SoC 102 described with reference to FIG. 1. For example, the memory device of the second semiconductor structure 204 can be an example of the memory 122, and the logic device 206 can be the SoC 102, and/or one or more other logic components of the SoC 102.

In some implementations, the second semiconductor structure 204 can be bonded to the first semiconductor structure 202, e.g., using hybrid bonding techniques. For example, the semiconductor device 200 can include a bonding structure 218 between the first semiconductor structure 202 and the second semiconductor structure 204. The bonding structure 218 can include conductive contacts and a dielectric material isolating the conductive contacts. The conductive contacts of the bonding structure 218 can be configured to transfer data and/or power between the first semiconductor structure 202 (e.g., logic circuits in the logic device 206) and the second semiconductor structure 204 (e.g., PIM units and/or memory cell arrays in the memory device).

In some implementations, the first semiconductor structure 202 can further include an interconnect layer 208 coupled to the logic devices 206. For example, the interconnect layer 208 can include one or more layers of vias and conductive interconnects connected to the logic devices 206. In some implementations, the interconnect layer 208 can include dielectric materials between the vias and the conductive interconnects. The interconnect layer 208 can be configured to transfer data signals between the logic devices 206 and other components of the semiconductor device 200.

In some implementations, the first semiconductor structure 202 can further include a carrier wafer 210 (or at least a portion of a carrier wafer) bonded to the interconnect layer 208.

In some implementations, the semiconductor device 200 can further include an interconnect layer 214 coupled to the second semiconductor structure 204. For example, the interconnect layer 214 can include power interconnects (also referred to as power grids) and can be configured to provide power to the components of the semiconductor device 200. The interconnect layer 214 can also be configured to transfer data signals between the semiconductor device 200 and an external component.

In some implementations, the semiconductor device 200 can further include conductive contacts 216 (e.g., micro bumps) coupled to the interconnect layer 214. The conductive contacts 216 can be used to provide electrical connections between the semiconductor device 200 and an external component.

FIG. 3 illustrates an example process 300 of manufacturing a semiconductor device, such as the semiconductor device 200 as illustrated in FIG. 2. FIG. 3 shows side views of example semiconductor structures at various stages of the fabrication process.

Operations 302-310 of the process 300 illustrate a process of forming a first semiconductor structure (e.g., the first semiconductor structure 202 of FIG. 2). Manufacturing the first semiconductor structure can include forming an ordered logic circuit component stack including: a first substrate, a transistor layer formed on the first substrate, and a first interconnect layer formed on the transistor layer and bonded to a carrier wafer.

At operation 302, the first substrate (e.g., a bare silicon wafer) is formed or provided.

At operation 304, the transistor layer (e.g., the logic device 206 of FIG. 2) can be formed on the first substrate. In some implementations, the transistor layer can be a front-end transistor layer.

At operation 306, the first interconnect layer (e.g., the interconnect layer 208 of FIG. 2) can be formed on the transistor layer. The first interconnect layer can include any number of layers of interconnects made of conductive materials such as metal.

At operation 308, the first interconnect layer can be bonded to a carrier wafer (e.g., the carrier wafer 210 of FIG. 2). The carrier wafer can provide support to other semiconductor structures during a manufacturing process of the semiconductor device. In some instances, the first interconnect layer can be bonded to the carrier wafer using Fusion bonding techniques (e.g., dielectric-to-dielectric bonding).

At operation 310, the first substrate can be removed from the ordered logic circuit component stack to obtain the first semiconductor structure. The first substrate can be removed by techniques such as, e.g., wafer grinding, chemical mechanical planarization (CMP), and/or an etching process. After the first substrate is removed, the transistor layer of the first semiconductor structure can be exposed. In some implementations, another interconnect layer (not shown in FIG. 3) can be formed on the transistor layer to prepare the first semiconductor structure and make it suitable for the following operations (e.g., extreme fine pitch hybrid bonding). As such, a top layer (e.g., on the transistor layer side) of the first semiconductor structure can have a layout scheme suitable for hybrid bonding.

Operations 312-314 of the process 300 illustrate a process of forming a second semiconductor structure (e.g., the second semiconductor structure 204 of FIG. 2).

At operation 312, a second substrate (e.g., another bare silicon wafer) can be formed or provided.

At operation 314, a memory layer can be formed on the second substrate. The memory layer can include one or more memory cell arrays. In some implementations, the memory layer can further include one or more PIM units coupled to the one or more memory cell arrays. The second semiconductor structure can include the second substrate and the memory layer. In some implementations, another interconnect layer (not shown in FIG. 3) can be formed on the memory layer to make the second semiconductor structure suitable for the following operations (e.g., hybrid bonding).

In some implementations, the first and second semiconductor structures can be fabricated separately (e.g., in parallel) such that a limitation (e.g., thermal budget) of fabricating one of them does not limit the processes of fabricating another.

At operation 316, the first semiconductor structure and the second semiconductor structure can be bonded using bonding techniques, such as, e.g., hybrid bonding. For example, during the hybrid bonding, a first bonding layer can be formed and coupled to the transistor layer of the first semiconductor structure. The first bonding layer includes first conductive contacts and a first dielectric material isolating the first conductive contacts. Similarly, a second bonding layer is formed and coupled to the memory layer of the second semiconductor structure. The second bonding layer can include conductive contacts and a second dielectric material isolating the second conductive contacts. A bonding structure between the first semiconductor structure and the second semiconductor structure can be formed by stacking the second bonding layer on the first bonding layer and bonding them together. The second conductive contacts are aligned with the first conductive contacts, and the bonding structure includes the first bonding layer and the second bonding layer.

In some implementations, both of the first and the second semiconductor structures can go through a surface activation process using plasma. The hybrid bonding process can further include a hydration step followed by molecular bonding at room temperature. To achieve stronger oxide bonding and inter-metal diffusion, the stacked first and second semiconductor structures can further go through annealing process.

At operation 318, after the hybrid bonding process (e.g., wafer-to-wafer bonding) is complete, the bonded structure can be flipped (such that the carrier wafer is at the bottom of the stack and the second substrate is at the top of the stack).

At operation 320, the second substrate (e.g., bulk silicon of the second semiconductor structure) can be removed using bulk silicon removal techniques such as grinding, CMP, etching, or Infrared based layer transfer/release mechanisms, etc.

At operation 322, a second interconnect layer can be formed on the memory layer and can be configured to provide power to the memory layer and the transistor layer. The second interconnect layer can include any number of layers of interconnects (e.g., metal).

At operation 324, third conductive contacts can be formed and coupled to the second interconnect layer to enable flip-chip packaging to substrate and system build. The third conductive contacts can be configured to provide electrical connections to an external component. In some instances, the third conductive contacts can be micro bumps (e.g., C4 bumps).

FIG. 4 illustrates a flow chart of an example process 400. The process 400 can be performed to form a semiconductor device (e.g., the SoC 102 of FIG. 1 or the semiconductor device 200 of FIG. 2). The process 400 can be described in view of FIG. 3. Moreover, the process 400 can include one or more steps of the fabrication process illustrated in FIG. 3. It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a first semiconductor structure (e.g., the first semiconductor structure described with reference to operations 302-316 of FIG. 3) is formed. The first semiconductor structure can include logic circuits (e.g., the transistor layer in operation 304 of FIG. 3) configured to perform logic processing functions.

At operation 404, a second semiconductor structure (e.g., the second semiconductor structure described with reference to operations 312-314 of FIG. 3) is formed. The second semiconductor structure can include one or more memory cell arrays (e.g., the memory layer in operation 314 of FIG. 3).

At operation 406, the second semiconductor structure is stacked over the first semiconductor structure (e.g., as described in operation 316 of FIG. 3).

At operation 408, the second semiconductor structure is bonded to the first semiconductor structure (e.g., using hybrid bonding techniques as described in operation 316 of FIG. 3).

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non transitory program carrier for execution by, or to control the operation of, data processing apparatus.

Alternatively or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus. The computer storage medium can be a machine-readable storage device, a machine-readable storage substrate, a random or serial access memory device, or a combination of one or more of them. The term “computing system” encompasses all kinds of apparatus, devices, and machines for processing data, including by way of example a programmable processor, a computer, or multiple processors or computers. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, or a combination of one or more of them.

A computer program (which may also be referred to or described as a program, software, a software application, a module, a software module, a script, or code) can be written in any form of programming language, including compiled or interpreted languages, or declarative or procedural languages, and it can be deployed in any form, including as a stand-alone program or as a module, component, subroutine, or other unit suitable for use in a computing environment.

A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub programs, or portions of code. A computer program can be deployed to be executed on one computer or on multiple computers that are located at one site or distributed across multiple sites and interconnected by a communication network.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., an FPGA (field programmable gate array), an ASIC (application specific integrated circuit), or a GPGPU (General purpose graphics processing unit).

Computers suitable for the execution of a computer program include, by way of example, can be based on general or special purpose microprocessors or both, or any other kind of central processing unit. Generally, a central processing unit will receive instructions and data from a read only memory or a random access memory or both. Some elements of a computer are a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described in this specification can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

What is claimed is:

1. A semiconductor device comprising:
a first semiconductor structure comprising logic circuits configured to perform logic processing functions;
a second semiconductor structure comprising a memory device, wherein the second semiconductor structure is stacked over the first semiconductor structure; and
a bonding structure between the first semiconductor structure and the second semiconductor structure.

2. The semiconductor device of claim 1, wherein the first semiconductor structure comprises a logic device, the logic device comprises the logic circuits, and the logic device comprises at least one of a central processing unit (CPU), a graphics processing unit (GPU), an application-specific integrated circuit (ASIC), an application processor (AP), a tensor processing unit (TPU), or a system-on-chip (SoC).

3. The semiconductor device of claim 1, wherein the memory device comprises one or more memory cell arrays.

4. The semiconductor device of claim 3, wherein the memory device further comprises one or more processor-in-memory (PIM) units coupled to the one or more memory cell arrays.

5. The semiconductor device of claim 1, wherein the bonding structure comprises conductive contacts and a dielectric material isolating the conductive contacts, and the conductive contacts are configured to transfer data and power between the logic circuits of the first semiconductor structure and the memory device of the second semiconductor structure.

6. The semiconductor device of claim 1, wherein the first semiconductor structure further comprises a first interconnect layer coupled to the logic circuits;
and wherein the semiconductor device further comprises a second interconnect layer coupled to the second semiconductor structure, wherein the second interconnect layer is configured to provide power to the first semiconductor structure and the second semiconductor structure.

7. A method for manufacturing a semiconductor device, comprising:
forming a first semiconductor structure comprising logic circuits configured to perform logic processing functions;
forming a second semiconductor structure comprising one or more memory cell arrays;
stacking the second semiconductor structure over the first semiconductor structure; and
bonding the second semiconductor structure to the first semiconductor structure.

8. The method of claim 7, wherein forming the first semiconductor structure comprises:
forming an ordered logic circuit component stack comprising: a first substrate, a transistor layer formed on the first substrate, and a first interconnect layer formed on the transistor layer and bonded to a carrier wafer; and
removing the first substrate from the ordered logic circuit component stack to obtain the first semiconductor structure.

9. The method of claim 8, wherein the first interconnect layer is bonded to the carrier wafer using a fusion bonding technique.

10. The method of claim 8, wherein the transistor layer comprises a logic device, the logic device comprises the logic circuits, and the logic device comprises at least one of a central processing unit (CPU), a graphics processing unit (GPU), an application-specific integrated circuit (ASIC), an application processor (AP), a tensor processing unit (TPU), or a system-on-chip (SoC).

11. The method of claim 8, wherein forming the second semiconductor structure comprises:
forming a second substrate; and
forming a memory layer on the second substrate, wherein the memory layer comprises the one or more memory cell arrays, and the second semiconductor structure comprises the second substrate and the memory layer.

12. The method of claim 11, wherein forming the memory layer further comprise:
forming one or more processor-in-memory (PIM) units in the memory layer.

13. The method of claim 11, wherein bonding the second semiconductor structure to the first semiconductor structure comprises:
bonding the memory layer of the second semiconductor structure to the transistor layer of the first semiconductor structure.

14. The method of claim 11, wherein the second semiconductor structure is bonded to the first semiconductor structure using a hybrid bonding technique, and wherein bonding the memory layer of the second semiconductor structure to the transistor layer of the first semiconductor structure comprises:
forming a first bonding layer coupled to the transistor layer, wherein the first bonding layer comprises first conductive contacts and a first dielectric material isolating the first conductive contacts;
forming a second bonding layer coupled to the memory layer, wherein the second bonding layer comprises second conductive contacts and a second dielectric material isolating the second conductive contacts; and
forming a bonding structure by bonding the second bonding layer to the first bonding layer, wherein the second conductive contacts are aligned with the first conductive contacts, and the bonding structure comprises the first bonding layer and the second bonding layer.

15. The method of claim 11, further comprising:
removing the second substrate from the second semiconductor structure; and
forming a second interconnect layer on the memory layer, wherein the second interconnect layer is configured to provide power to the memory layer and the transistor layer.

16. The method of claim 15, further comprising:
forming third conductive contacts coupled to the second interconnect layer, wherein the third conductive contacts are configured to provide electrical connections to an external component.

17. A semiconductor device comprising:
a first semiconductor structure comprising a first device;
a second semiconductor structure comprising a second device; and
a bonding structure between the first semiconductor structure and the second semiconductor structure.

18. The semiconductor device of claim 17, wherein the first device comprises at least one of a first logic device or a first memory device, the first logic device comprises first logic circuits configured to perform logic processing functions, and the first memory device comprises one or more first memory cell arrays.

19. The semiconductor device of claim 17, wherein the second device comprises at least one of a second logic device or a second memory device, the second logic device comprises second logic circuits configured to perform logic processing functions, and the second memory device comprises one or more second memory cell arrays.

20. The semiconductor device of claim 17, wherein the bonding structure comprises conductive contacts and a dielectric material isolating the conductive contacts, and the conductive contacts are configured to transfer data and power between the first device and the second device.
